(19) United States
(12) Patent Application Publication
(10) Pub. No.: US 2020/0133431 A1
(43) Pub. Date: Apr. 30, 2020

(54) PCB WITH INTEGRATED TOUCH SENSORS

(71) Applicant: Google LLC, Mountain View, CA (US)

(72) Inventors: Joseph Allore, Mundelein, IL (US); Michael J. Lombardi, Lake Zurich, IL (US); Sajid Dalvi, Aurora, IL (US); Mitchell T. Hodges, Plainfield, IL (US); Krzysztof Szot, Carol Stream, IL (US)

(21) Appl. No.: 16/176,778

(22) Filed: Oct. 31, 2018

(51) Int. Cl. G06F 3/042; G06F 3/01; G06F 3/041; G06F 3/0488; F21V 8/00; H05K 1/02

(52) U.S. Cl. CPC G06F 3/0421; G06F 3/016; H05K 1/0213; G06F 3/0488; G02B 6/0073; G06F 3/0416

(57) ABSTRACT

An electrical control system includes a switch module configured to control power delivery to at least one external load, and a removable user interface module configured to connect to the switch module, receive power from the switch module and display an interface in accordance with a status of the external load, the user interface including a printed circuit board (PCB) having a touch controller that detects signals from a plurality of touch sensors integrated on a first side of the PCB, and a light-emitting diode (LED) controller that controls a plurality of LED's, a light guide, attached to the first side of the PCB, that partially obstructs light emitted from the plurality of LED's, a tactile switch electrically connected to the first side of the PCB between the transparent cover and the PCB, and a cover attached to the tactile switch over the first side of the PCB.

### BACKGROUND

It will be appreciated that this Background section represents the observations of the inventors, which are provided simply as a research guide to the reader. As such, nothing in this Background section is intended to represent, or to fully describe, prior art.

Lighting controls remain one of the most common devices in the world. They are in nearly every country, in most homes and rooms. In addition to widespread use, the appearance and functionality of the basic light switch remains virtually identical to what was provided in the original disclosure of the toggle light switch in 1917. However, newer functions like dimming, motion-based activation and programmed lighting schedules have been implemented in various forms. Companies have also integrated modern connectivity solutions into the standard light switch, allowing it to be controlled remotely via smartphone or other electronic device.

### BRIEF SUMMARY

According to an embodiment of the disclosed subject matter, an electrical control system for installation in an electrical box of a premises includes a switch module configured to control power delivery to at least one external load and a removable user interface module configured to connect to the switch module, receive power from the switch module and display an interface in accordance with a status of the external load, the user interface including a printed circuit board (PCB) having a touch controller that detects signals from a plurality of touch sensors integrated on a first side of the PCB, and a light-emitting diode (LED) controller that controls a plurality of LED's, a light guide, attached to the first side of the PCB, that partially obstructs light emitted from the plurality of LED's, a tactile switch electrically connected to the first side of the PCB between the transparent cover and the PCB and a cover attached to the tactile switch over the first side of the PCB.

According to another embodiment of the disclosed subject matter, a user interface device, comprising a rear housing, a hinge assembly connected to the rear housing, a front cover connected to the hinge assembly, a printed circuit board (PCB) disposed between the front cover and rear housing, the PCB including a plurality of touch sensors integrated on a first side of the PCB, a touch controller that determines a first type of input based on signals from the plurality of touch sensors, and a processor that receives the first type of input and executes a first operation based on the first type of input, and a tactile switch electrically connected to the first side of the PCB between the front cover and the PCB, wherein the processor determines a second type of input based on signals from the tactile switch and executes a second operation based on the second type of input.

Additional features, advantages, and embodiments of the disclosed subject matter may be set forth or apparent from consideration of the following detailed description, drawings, and claims. Moreover, it is to be understood that both the foregoing summary and the following detailed description are illustrative and are intended to provide further explanation without limiting the scope of the claims.

### BRIEF DESCRIPTION OF THE DRAWINGS

The accompanying drawings, which are included to provide a further understanding of the disclosed subject matter, are incorporated in and constitute a part of this specification. The drawings also illustrate embodiments of the disclosed subject matter and together with the detailed description serve to explain the principles of embodiments of the disclosed subject matter. No attempt is made to show structural details in more detail than may be necessary for a fundamental understanding of the disclosed subject matter and various ways in which it may be practiced.

FIG. 1 shows an electrical control system according to an embodiment of the disclosed subject matter.

FIG. 2 shows an angled view of a user interface module according to an embodiment of the disclosed subject matter.

FIG. 3 shows an exploded, angled view of a user interface module from the front according to an embodiment of the disclosed subject matter.

FIG. 4 shows an exploded view of a user interface module from the rear according to an embodiment of the disclosed subject matter.

FIG. 5 shows a printed circuit board (PCB) with integrated touch sensors according to an embodiment of the disclosed subject matter.

FIG. 6 shows a PCB with light guides according to an embodiment of the disclosed subject matter.

FIG. 7 shows an example setting of an electrical control system according to an embodiment of the disclosed subject matter.

FIG. 8 shows a cut-away side view of a PCB including a tactile switch according to an embodiment of the disclosed subject matter.

FIG. 9 shows an exploded view of a switch module according to an embodiment of the disclosed subject matter.

FIG. 10 shows another exploded view of a switch module according to an embodiment of the disclosed subject matter.

FIG. 11A shows a block diagram of a switch module and user interface module according to an embodiment of the disclosed subject matter.

FIG. 11B shows an example configuration of a relay circuit and TRIAC of a switch circuit according to an embodiment of the disclosed subject matter.

### DETAILED DESCRIPTION

The following description is based on embodiments of the disclosed principles and should not be taken as limiting the claims with regard to alternative embodiments that are not explicitly described herein. Also, various aspects or features of this disclosure are described with reference to the drawings, wherein like reference numerals are used to refer to like elements throughout.

In this specification, numerous details are set forth in order to provide a thorough understanding of this disclosure. It should be understood, however, that certain aspects of disclosure may be practiced without these specific details, or with other methods, components, materials, etc. In other instances, well-known structures and devices are depicted in block diagram form to facilitate describing the subject disclosure.

Lighting controls are frequently found at the entry points of rooms within residential, commercial and industrial buildings. They are installed within switch boxes which are typically attached to the underlying structure of the building. Lighting controls have a standardized attachment scheme such that they can be installed, replaced and/or upgraded over time without modification to the switch box. Multiple lighting controls can control a single load, resulting in three-way or multi-way switch configurations.

A traditional simple light switch is essentially a mechanical switch device that does not require a power source to operate and operates solely in a toggle mode. Likewise, a traditional dimmer switch is normally implemented as a mechanical knob or sliding lever that can be used to adjust a variable resistor that controls a triode for alternating current (TRIAC).

The disclosed embodiments of a smart electrical control system includes a switch module that can operate in either a dimmer mode or a toggle mode and a detachable user interface including one or more integrated touch sensors that receive touch input from a user and a light guide display that shows a status of the load being controlled by the switch module. By integrating the touch sensors, light guides, and switch components on a single printed circuit board (PCB) design and manufacturing costs are significantly reduced.

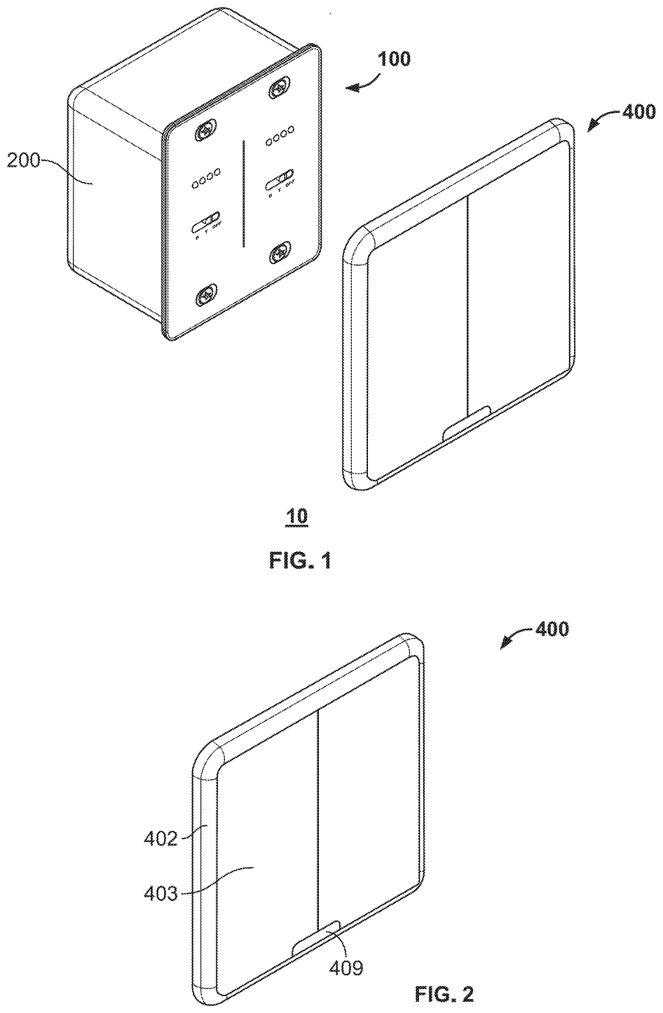

FIG. 1 depicts an embodiment of an electrical control system 10 according to the disclosed subject matter, including a switch box 200 housing a switch module 100 that draws power for the system 10 and implements switch functionality, and a user interface (UI) module 400 to provide a user with an interface to control the system 10. The configuration depicted is a dual-gang (two circuit) configuration, however, the switch module 100 and UI module 400 can be made in various configurations to accommodate different size and feature requirements.

FIG. 2 is an angled view of a UI module 400 according to the disclosed subject matter. The UI module includes a lens 403 and front housing 402. A sensor lens 409 is included in this embodiment. As will be described below, the UI module 400 provides controls for smart switch functionality based on a mode (e.g., toggle/dimmer) that the smart electrical control system 10 is set in.

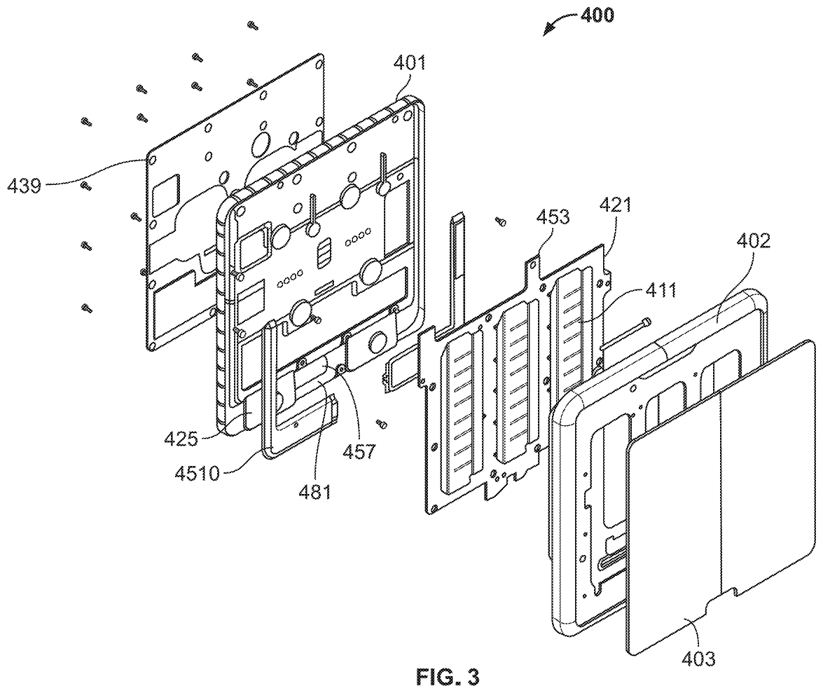

FIG. 3 is an exploded, angled view of an embodiment of the UI module 400 from the front and illustrates an example layout of some of its powered internal components. In this layout an infrared (IR) motion sensor 457 is oriented towards a mirror 481 to direct the light from the sensor lens 409 (FIG. 2) towards the IR motion sensor 457. One or more speakers 425 may be located within an acoustic housing 4510 and connected to a printed circuit board (PCB) assembly 421, which includes a processor and various controllers. The PCB assembly 421 can include a microphone 453. The PCB assembly 421 also may include, beneath a light guide assembly 411, a plurality of LEDs (not depicted) to provide output and a plurality of touch sensors (not depicted) to receive input. To diffuse the light emitted by the LEDs, the light guide assembly 411 can be implemented as molded plastic, film sheets, or the like. A rear cover 439 attaches to the rear housing 401.

The UI module 400 can display an interface for smart switch functionality in various modes, such as toggle mode or dimmer mode. For example, the PCB assembly 421 can control the LED's to display lighting through the light guide assembly 411 according to a current mode setting and thereby indicate a state of the load (e.g. a current light setting, fan setting, etc), or provide other audio/visual information to a user. The lens 403 can include a printed layer such as an additional masked pattern that allows light to be emitted only in certain areas, for example to aid in creating a display suitable for a given mode.

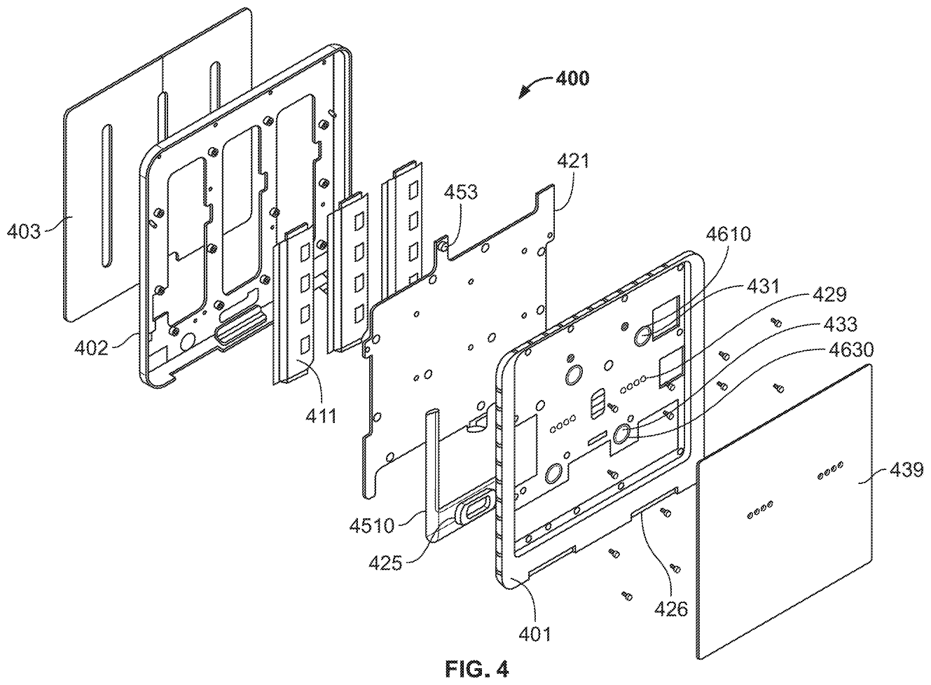

FIG. 4 is an exploded, angled view of an embodiment of the UI module 400 from the rear, depicting an example layout of various components that interact with the switch module 100 (FIG. 1). The UI module 400 includes a mechanism for attaching or fastening to an underlying switch module 100. The mechanism can be implemented, for example, via magnets, hooks, slots, clips or other types of fasteners. As will be described below, the UI module can also include a data transmission system to communicate with the switch module, for example, pins or a transceiver, an IR light emitter and IR light detector or the like, and a power transmission system to supply power to or receive power from a switch module.

The embodiment depicted in FIG. 4 includes contact pins 429 to receive/transmit power and transmit/receive data, and retention magnets 431, 433 surrounded by ferrous steel shrouds 4610, 4630 to attach to the switch module 100. One or more audio ports 426 can be formed in the rear housing 401.

The UI module 400 is not limited to the embodiments or component layouts depicted in FIGS. 3-4, but can also be constructed with different layouts and include other sensors, for example, to detect temperature, humidity, ambient light, motion, and so on. In one embodiment, a UI module 400 can include one or more of a video camera, LCD display, ambient light sensor, and IR motion sensor.

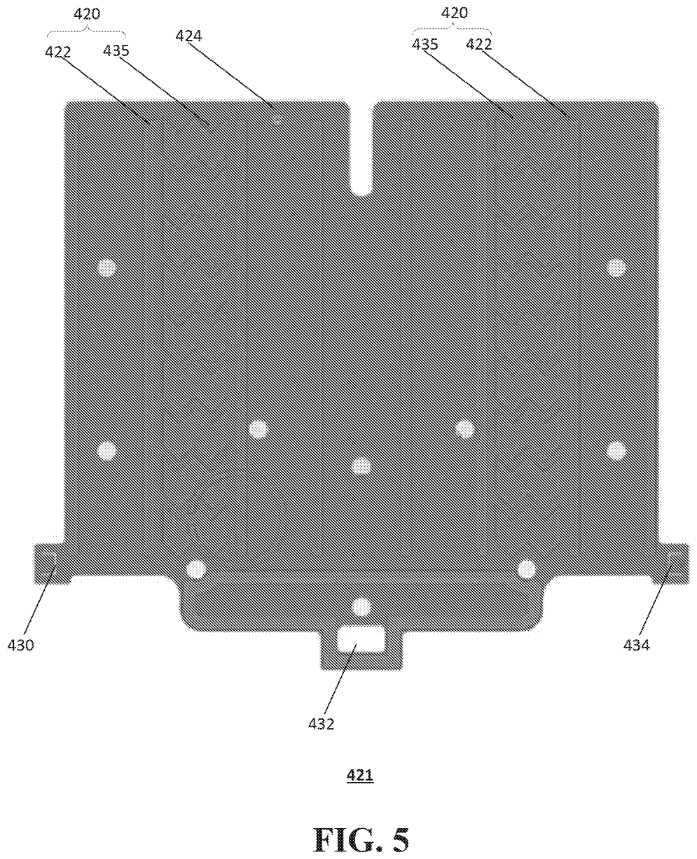

FIG. 5 shows a view of part of the PCB assembly 421, including one or more sensors (e.g., ambient light sensor 424, temp sensor 430, humidity sensor 434) and touch sensors 420 formed of one or more capacitive trip lines 422 and one or more capacitive touch slider strips 435. The assembly 421 can also include a near field communication (NFC) antenna 432.

The capacitive trip lines 422 and capacitive touch slider strips 435 can be etched directly on the PCB 421 using, for example, copper or indium tin oxide (ITO), and electronically connected to a processor. When a human finger comes in close proximity to one of the segments of touch sensor 420, e.g., by swiping or touching the lens cover 403 (FIG. 3) of the UI module 400, the capacitance of the segment of trip lines 422 and/or slider strips 435 near the finger changes. A touch controller can detect the change, determine the approximate location of the human finger and derive an input corresponding to the determined location.

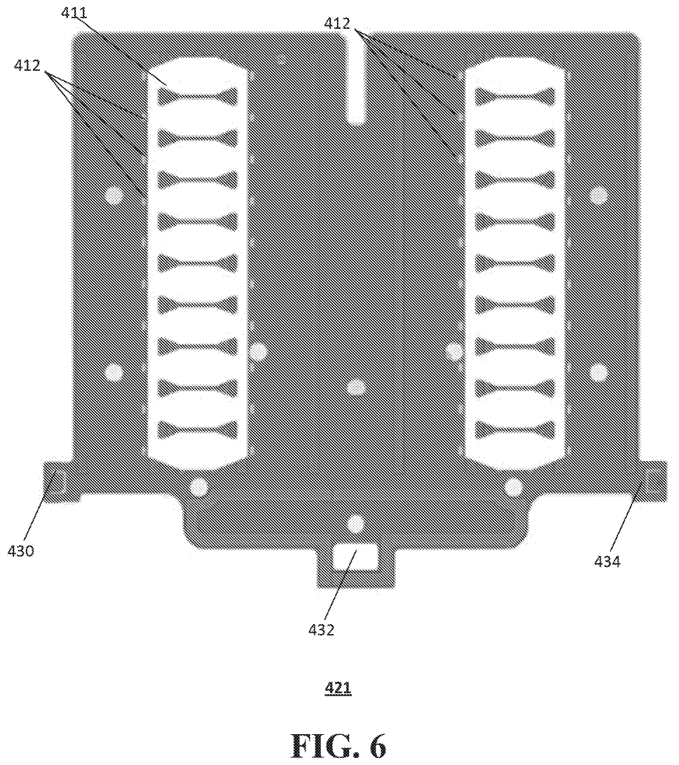

FIG. 6 shows part of the PCB 421 with light guides 411 installed. A plurality of LED's 412 emit light through openings in the light guides 411. The light guides partially obstruct light emitted from the LED's 412.

In one embodiment, as shown in FIG. 6, the LED's 412 are disposed along opposing edges of the light guide 411. In this layout the LED's 412 emit light primarily parallel to a plane in which the light guide 411 is disposed. A diminished amount of light passes through the light guide 411 openings, producing a dampened or soft light appearance through the front lens cover 403 (FIG. 3). In one embodiment the LED's 412 can be disposed under the light guide 411, that is, between the light guide 411 and the PCB 421. This will produce a sharper light output.

The lens cover 403 can further include a non-transparent portion and a translucent portion formed in a shape and size that corresponds to the light guide 411. The translucent portion can be positioned in alignment with the light guide 411 to further control the light output. The lens cover 403 can also include a printed pattern markings that aligned with the LED's 412 to indicate settings available to a load controlled by the UI module 400.

The LED's 412 can include multiple colors, for example, at least two different colors can be arranged in an alternating pattern on either side of the light guide 411, or arranged to display a first color on a first side of the light guide 411 and a second color on a second side of the light guide 411. The UI module 400 can display different types of outputs using the multiple colors. For example, a first color can correspond to a first load controlled by the UI module 400 and a second color can correspond to a second load controlled by the UI module 400.

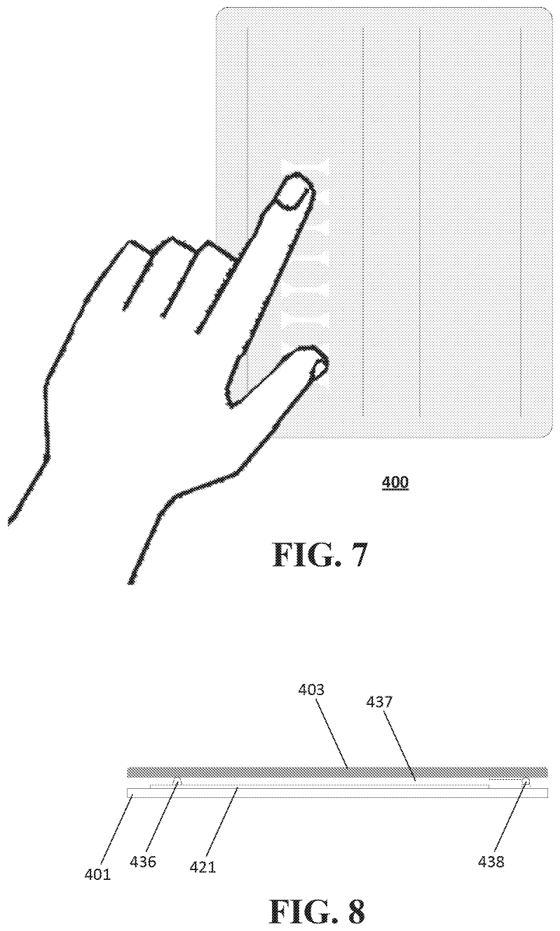

FIG. 7 shows an example display of the lens cover 403 in one embodiment of the disclosed UI module 400. A plurality of LED's (not shown) are switched on in response to the touch of a user sliding a finger on the lens cover 403. The LED's can be configured to activate in a pattern responsive to the position of the detected touch.

In the disclosed embodiments the UI module 400 can also receive input via a tactile switch disposed between the lens cover 403 and the PCB 421. FIG. 8 shows a cut-away side view of the UI module 400, showing a tactile switch 436 and hinge assembly 438. Tactile switch 436 can be disposed on the PCB 421. Hinge assembly 438 can be disposed on the rear housing 401. An air gap 437 exists between the front lens cover 403 and the PCB 421 to allow for travel of the front lens cover 403 into the tactile switch 436. When a user presses on the lens cover 403, the lens cover 403 presses the tactile switch 436, which will actuate and trigger an input on PCB 421. The received input can be used to control various events, such as lighting control, fan control, etc. An indicator can be included on the front cover 109 to show a region for the user to press to actuate the switch module.

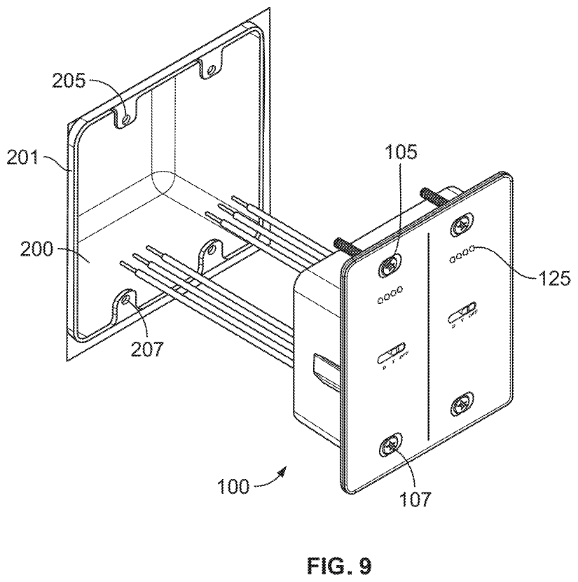

Turning now to details of the disclosed switch module that powers the UI module 400, FIG. 9 depicts an angled, exploded view of a switch module assembly in switch box 200 with a wall plate 300 for covering the finished installation. The switch box 200 has threaded holes 205, 207 to retain the switch module 100 using screws 105, 107. In typical applications, the switch box 200 is surrounded by building material 201 such as drywall. In the embodiment depicted, two switch modules 100, 150 are installed into the same switch box 200. The switch modules 100, 150 may be identical or have functional variations such as the ability to dim a light, control a fan, etc. In this embodiment the wall plate 300 includes a cutout 301 centered over the IR light emitter (not depicted) and IR light detector (not depicted).

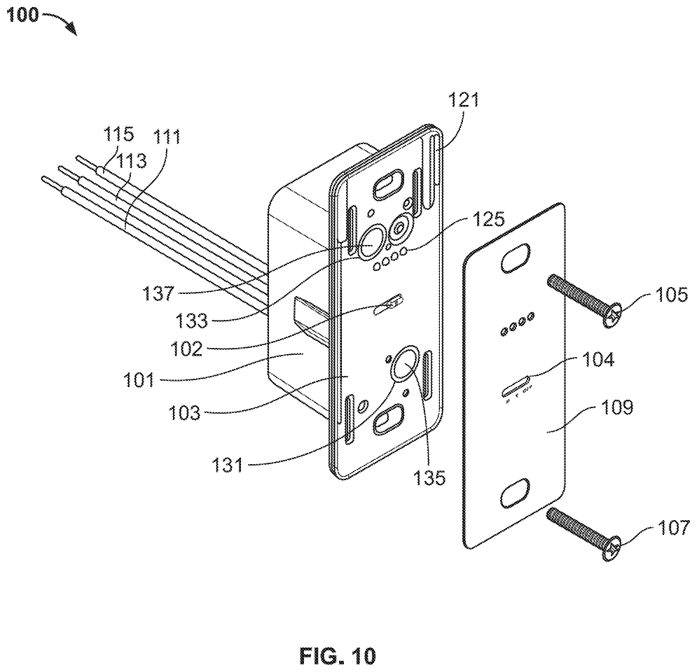

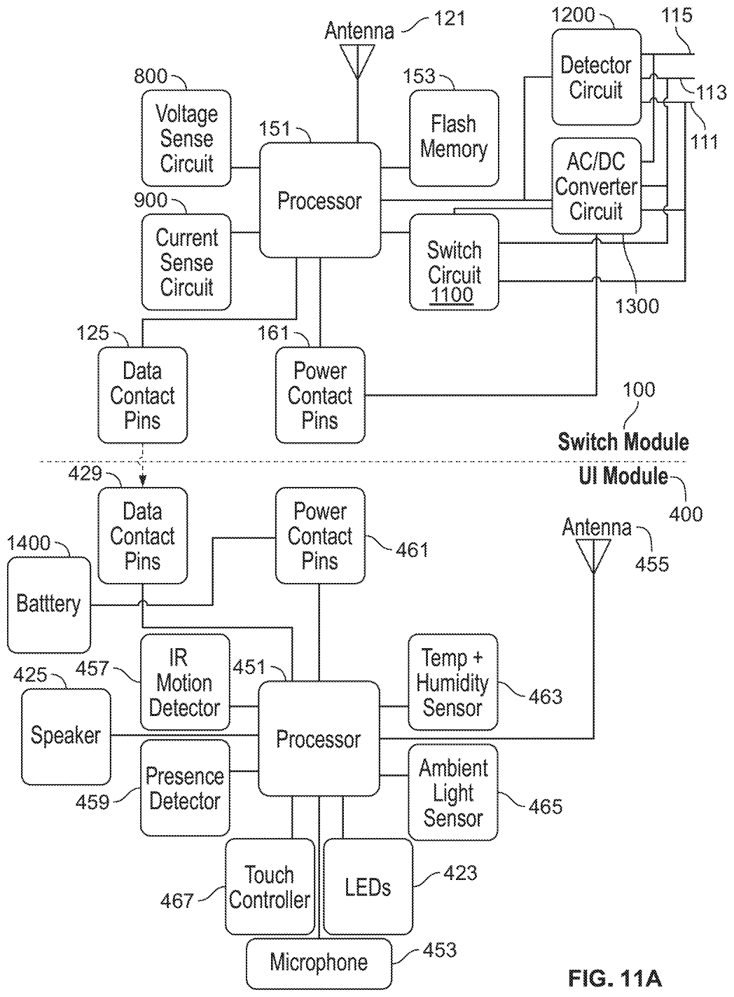

FIG. 10 is an angled, exploded view of a switch module 100 in a single-gang configuration. A first screw 105 and second screw 107 are used to retain the switch module 100 to a switch box. The switch module 100 includes front cover 109, front housing 103, and a main housing 101 that holds most of the internal components of the switch module 100, including a printed circuit board PCB assembly (not shown). The layout and configuration of the PCB and internal components can change based on the implementation of different features.

The switch module 100 incudes a plurality of connectors 111, 113, 115 for connecting the switch module 100 to a building's existing electrical wiring, e.g., through a gang box. The connectors 111, 113, 115 allow the switch module 100 to draw electrical power from the building and to execute switching functionality for the load (e.g., light, fan, etc.) that the switch module 100 is installed to control.

In the main housing 101, the switch module 100 can include a power transmission system to transmit power to the UI 400, for example, using contacts or a wireless power transmission coil. The embodiment depicted in FIG. 6 includes contact pins 125 configured to transmit power to a UI module (not shown) when attached to the UI module.

The switch module 100 includes an antenna 121 disposed behind the front cover 109 to allow wireless communication with external electronic devices, e.g., smart phones, tablets, laptops, smart watches, etc. The antenna also can be used by one switch module to communicate with another switch module, for example, using wireless networking standards such as IEEE 802.15.4, which higher level protocols such as ZigBee and Thread are based on. Thus, multiple switch modules throughout a home can communicate with each other. In other embodiments, the switch module may offer no wireless connectivity and such connectivity may be included in the UI module.

Instead of peer-to-peer or one-to-many network topologies, a plurality of switch modules installed in a home may form a mesh network such that a single point of failure does not impact connectivity for other devices in the home. When a UI module 400 physically docks over a switch module 100 that is connected to the wireless mesh, the UI module 400 can use the contact pins 125 to communicate with the underlying switch module 100 and send commands and/or data through the mesh network instead of directly joining the wireless mesh. Using this configuration a UI module 400 can control any switch module on the mesh network and is not limited to controlling a switch module physically connected to the UI module.

Referring back to FIG. 10, the switch module 100 can also include a mechanism for attaching or fastening to the UI module, for example, magnets, hooks, slots, clips or other types of fasteners. In the embodiment depicted, two magnets 135, 137 are disposed behind the front cover 109, surrounded by two ferrous steel shrouds 131, 133 on all sides other than the side facing the front cover 109. The magnets 135, 137 can passively maintain a force that can be used to hold a UI module against the switch module 100, providing an additional advantage of reducing the number of parts that require interlocking or clicking that are susceptible to wear and tear.

The switch module 100 can also include a data transmission system, for example, contact pins, a transceiver, an infrared (IR) light emitter and IR light detector or the like. In one embodiment, the IR light emitter and IR light detector on the switch module 100 may be part of the same physical component. In the embodiment depicted in FIG. 6 contact pins 125 protrude through the front cover 109 and function as a data transmission system.

The switch module 100 itself can also implement a tactile switch (not shown) such that if a user presses on a front face of the switch module 100 the tactile switch will actuate and trigger an input to control a load, such as a light or fan, or trigger execution of an operation on a different device, such as turn on/off a radio. An indicator can be included on the front cover 109 to show a region for the user to press to actuate the switch module.

The switch module 100 can also include a slidable switch 102 disposed behind the front cover 109. The slidable switch 102 is accessible through opening 104 in the front cover 109. The slidable switch 102 enables a user to control the switch module 100 to implement various operating modes, such as dimmer (TRIAC-based) or toggle (relay-based) operation modes.

Turning now to cooperation between the UI module 400 and the switch module 100, referring to FIGS. 4 and 10, retention magnets 431, 433 are positioned to draw the UI module 400 into alignment with the magnets 135, 137 of the switch module 100. In this manner, the UI module 400 is automatically retained in proper alignment and position with the switch modules 100 by the retention force of the magnets.

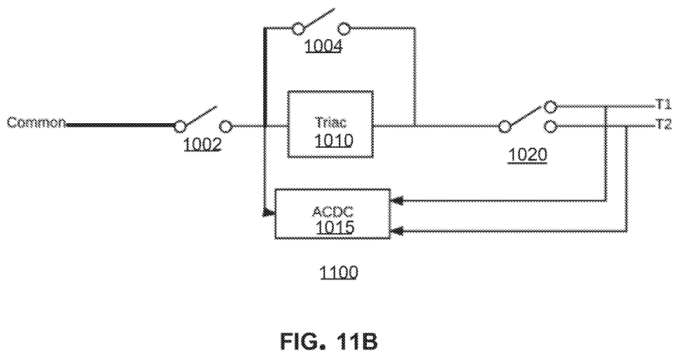

FIG. 11A is a block diagram of the switch module 100 and the UI module 400. The switch module 100 includes a processor 151 which controls functions executed by the switch module 100. The processor 151 may also comprise its own memory, modem and/or other functions to comprise a “system on a chip” (SoC). The switch module 100 can include a Hall Effect sensor (not depicted) connected to the processor 151 and can include one or more secondary processors (not depicted) to handle certain designated functions or to otherwise aid the processor 151. The switch module 100 also powers contact pins 161 that are capable of transmitting power to the UI module 400.

Processor 151 can transmit data and commands to the UI module 400 via data contact pins 125. Data contact pins 125 can be separate from power contact pins 161 or can be one and the same. The switch module 100 can include flash memory 153 external to the processor 151. The switch module 100 also includes an antenna 121 connected to the processor 151. The switch module 100 further includes a switch circuit 1100, detector circuit 1200, and AC-DC converter circuit 1300 connected to and controlled by the processor 151.

The switch circuit 1100 can include a relay circuit, a triode for alternating current (TRIAC) circuit, and a mode-selectable circuit that allows a user to choose between use of a relay and a TRIAC for controlling the current delivered to a load.

FIG. 11B depicts a block diagram of a switch circuit 1100 which can be included in an embodiment of the disclosed switch module 100. The switch circuit 1100 includes a first relay 1002, a second relay 1004, a TRIAC 1010, an AC-to-DC converter circuit 1015, and a third relay 1020. Additional components not depicted can be included in the switch circuit 1100. The setting of the first relay 1002 and second relay 1004 can be controlled by the slidable switch 102 (FIG. 6). That is, in one configuration first relay 1002, for example, can be opened by moving the slidable switch 102 into a first position, second relay 1004 can be opened by moving slidable switch 102 moving into a second position, and both relays 1002, 1004 can be simultaneously closed by moving the slidable switch 102 into a third position.

The two relays 1002, 1004 and TRIAC 1010 can enable either of a toggle or dimmer mode of operation. That is, if the user wishes to control a load using on/off toggle commands without dimming, the user can move the slidable switch to the third position to set the first relay 1002 and the second relay 1004 both closed. If the user wishes to control a load using dimming functionality, the user can move the slidable switch into the second position to set the first relay 1002 closed and second relay 1004 open. Whenever the user wishes to cease providing power to the load the user can move the slidable switch to the first position to set the first relay 1002 open, thereby creating an air gap in the switch circuit 1100 between the common terminal and the load.

Referring back to FIG. 11A, the switch module 100 can include a voltage sense circuit 800 and a current sense circuit 900. These circuits allow the switch module 100 to monitor amounts of power used by the load attached to it.

The UI module 400 has a processor 451 that can be similar to that of the switch module 100. The processor 451 may have additional components and functionality embedded to comprise a SoC. The UI module 400 can include an antenna 455 which allows two way data communication using protocols such as WiFi. Additional antennas and wireless protocols may be implemented as well but are omitted from the illustration for simplification.

The UI module 400 can include data contact pins 429 and power contact pins 461 to receive/transmit data from the processor 451 and to receive power from the switch module 100 to power the UI module 400 components and charge battery 1400. Data contact pins 429 can be separate from power contact pins 461 or can be one and the same. In one implementation the processor 451 can transmit a status request to the switch module 100 to check, for example, which mode the switch module 100 is set in or a state of the load controlled by the switch module 100. Based on the received response, the processor 451 can control the UI module 400 to display an appropriate interface. In this way the UI module 400 can display an interface in accordance with setting of the slidable switch that sets the switch module 100 operational mode.

The UI module 400 also includes a speaker 425 and microphone 453 connected to the processor 451. As previously mentioned, LEDs 423 are included in the UI module 400 and are connected to and controlled by the processor 451 to, for example, display a load status or function as part of an interface. A variety of sensors can be connected to the processor 451, including: temperature and humidity 463, ambient light 465, touch 467, presence 459 and motion 457.

The disclosed electrical control system can function as part of a smart-home environment which can include a structure, such as, for example, an apartment, office building, garage, factory, mobile home, or the like. The electrical control system can control and/or be connected to devices and systems inside or outside of the structure.

In summary, the disclosed user interface module includes a PCB configured to include a touch controller, LED controller and implement a tactile switch electrically connected to the PCB. The disclosed PBC also has a plurality of touch sensors integrated into one or more of the etched copper layers of the PCB itself. Immediately above the PCB is a light guide which can include a series of multiple white and colored LEDs that side-fire into two edges of the light guide. Above the light guide is a cavity of air to allow for unimpeded travel of a hinged button assembly into the actuator of a tactile switch. Thus, an extremely efficient, low-cost physical button with touch functionality and backlighting for an electrical control system is disclosed.

The foregoing description, for purpose of explanation, has been described with reference to specific embodiments. However, the illustrative discussions above are not intended to be exhaustive or to limit embodiments of the disclosed subject matter to the precise forms disclosed. Many modifications and variations are possible in view of the above teachings. The embodiments were chosen and described in order to explain the principles of embodiments of the disclosed subject matter and their practical applications, to thereby enable others skilled in the art to utilize those embodiments as well as various embodiments with various modifications as may be suited to the particular use contemplated.

1. An electrical control system for installation in an electrical box of a premises, comprising:
a switch module configured to control power delivery to at least one external load; and
a removable user interface module configured to connect to the switch module, receive power from the switch module and display an interface in accordance with a status of the external load, the user interface including:
a printed circuit board (PCB) including:
a touch controller that detects signals from a plurality of touch sensors integrated on a first side of the PCB, and
a light-emitting diode (LED) controller that controls a plurality of LED's;
a light guide, attached to the first side of the PCB, that partially obstructs light emitted from the plurality of LED's;
a tactile switch electrically connected to the first side of the PCB between the transparent cover and the PCB; and
a cover attached to the tactile switch over the first side of the PCB.

2. The electrical control system of claim 1, wherein the plurality of LED's are aligned along opposing edges of the light guide.

3. The electrical control system of claim 2, wherein the plurality of LED's include at least two different colors disposed in an alternating pattern.

4. The electrical control system of claim 1, wherein the tactile switch comprises a hinged button assembly that travels toward the PCB.

5. The electrical control system of claim 1, wherein the cover comprises a non-transparent plate including a translucent portion aligned over the light guide.

6. The electrical control system of claim 5, wherein the cover further comprises a protective glass plate attached to the non-transparent plate.

7. A user interface device, comprising:
a rear housing;
a hinge assembly connected to the rear housing;
a front cover connected to the hinge assembly;
a printed circuit board (PCB) disposed between the front cover and rear housing, the PCB including:
a plurality of touch sensors integrated on a first side of the PCB;
a touch controller that determines a first type of input based on signals from the plurality of touch sensors, and
a processor that receives the first type of input and executes a first operation based on the first type of input; and
a tactile switch electrically connected to the first side of the PCB between the front cover and the PCB,
wherein the processor determines a second type of input based on signals from the tactile switch and executes a second operation based on the second type of input.

8. The user interface device of claim 7, further comprising a plurality of light-emitting diodes (LED's) disposed between the front cover and the PCB, wherein the processor controls the plurality of LED's based at least in part on the first type of input determined from the plurality of touch sensors.

9. The user interface device of claim 8, wherein the plurality of LED's include at least two different colors disposed in an alternating pattern.

10. The user interface device of claim 8, further comprising a light guide, attached to the first side of the PCB, that partially obstructs light emitted from the plurality of LED's.

11. The user interface device of claim 10, wherein the plurality of LED's are aligned along opposing edges of the light guide.

12. The user interface device of claim 7, wherein the cover comprises a non-transparent plate including a translucent portion aligned over the light guide.

13. The user interface device of claim 12, wherein the cover further comprises a protective glass plate attached to the non-transparent plate.
